(19) United States
(12) Patent Application Publication
(10) Pub. No.: US 2022/0259729 A1
(43) Pub. Date: Aug. 18, 2022

(54) DEPOSITION SYSTEM AND DEPOSITION METHOD

(71) Applicant: Tokyo Electron Limited, Tokyo (JP)

(72) Inventors: Youngtai KANG, Yamanashi (JP); Yuichi TAKENAGA, Yamanashi (JP); Juhyeong LEE, Yamanashi (JP)

(21) Appl. No.: 17/650,117

(22) Filed: Feb. 7, 2022

(30) Foreign Application Priority Data
Feb. 17, 2021 (JP) 2021-023598

(51) Int. Cl. C23C 16/455; C23C 16/52

(52) U.S. Cl. CPC C23C 16/45527; C23C 16/52

(57) ABSTRACT

A deposition system includes a deposition apparatus configured to deposit a film on a substrate, and a control device. The control device includes a recipe storage unit configured to store a recipe that defines a procedure of a substrate processing process performed by the deposition apparatus, and a processor configured to calculate a predicted value of a change amount from a target value of a control target indicating a film thickness or a film quality of a film deposited in a deposition step included in the substrate processing process, by using log information about the deposition apparatus, the log information being collected from when the substrate processing process based on the recipe starts, and update the recipe based on the predicted value so as to change a value of the control target to approach the target value before the deposition step.

### CROSS-REFERENCE TO RELATED APPLICATIONS

This patent application is based on and claims priority to Japanese Patent Application No. 2021-023598 filed on Feb. 17, 2021, the entire contents of which are incorporated herein by reference.

### TECHNICAL FIELD

The present disclosure relates to a deposition system and a deposition method.

### BACKGROUND

Conventionally, a deposition apparatus that deposits a desired film on a substrate, such as a semiconductor wafer is known. Additionally, in a conventional deposition apparatus, it is known that a film is deposited by using the optimum substrate processing conditions calculated by using a process model (for example, Patent Document 1).

### RELATED ART DOCUMENT

### [Patent Document]

[Patent Document 1] Japanese Laid-open Patent Application Publication No. 2017-168728

### SUMMARY

According to one aspect of the present disclosure, a deposition system includes a deposition apparatus configured to deposit a film on a substrate, and a control device. The control device includes a recipe storage unit configured to store a recipe that defines a procedure of a substrate processing process performed by the deposition apparatus, and a processor configured to calculate a predicted value of a change amount from a target value of a control target indicating a film thickness or a film quality of a film deposited in a deposition step included in the substrate processing process, by using log information about the deposition apparatus, the log information being collected from when the substrate processing process based on the recipe starts, and update the recipe based on the predicted value so as to cause a value of the control target to approach the target value before the deposition step.

### BRIEF DESCRIPTION OF THE DRAWINGS

FIG. 1 is a diagram for explaining a deposition system according to a present embodiment;

FIG. 2 is a diagram for explaining an outline of an operation of the deposition system according to the present embodiment;

FIG. 3 is a diagram illustrating an example of a hardware configuration of a control device according to the present embodiment;

FIG. 4 is a diagram for explaining a function of the control device according to the present embodiment;

FIG. 5 is a diagram illustrating an example of results of multivariate analysis according to the present embodiment;

FIG. 6A and FIG. 6B are graphs each indicating a correlation between a value of a change factor parameter and a change in a film thickness according to the present embodiment;

FIG. 7 is a graph for explaining a relationship between a step included in a substrate processing process and a correlation between the change factor parameter and the film thickness according to the present embodiment;

FIG. 8 is a diagram for explaining a relationship between a prediction model and a control model according to the present embodiment;

FIG. 9 is a flowchart illustrating the operation of the control device according to the present embodiment;

FIG. 10 is a first diagram for explaining processing of the control device according to the present embodiment; and

FIG. 11 is a second diagram for explaining the processing of the control device according to the present embodiment.

### DETAILED DESCRIPTION OF EMBODIMENTS

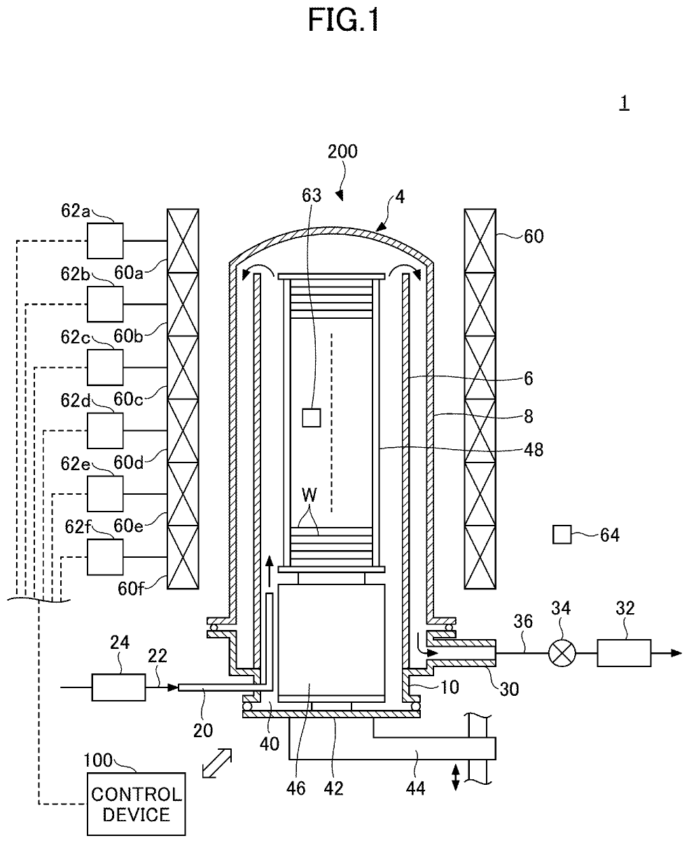

An embodiment will be described below with reference to the drawings. FIG. 1 is a diagram for explaining a deposition system according to a present embodiment.

A deposition system 1 according to the present embodiment includes a control device 100 and a deposition apparatus 200. In the deposition system 1, the control device 100 and the deposition apparatus 200 are connected by a suitable communication means.

In the deposition system 1 according to the present embodiment, the control device 100 is a computer that controls an operation of the deposition apparatus 200. The deposition apparatus 200 deposits a film having a desired film thickness and film quality on a substrate, such as a semiconductor wafer, according to control performed by the control device 100.

That is, the control device 100 controls the deposition apparatus 200 to control the film thickness and film quality of the film to be deposited. In the following description, the film thickness and film quality of the film to be deposited may be expressed as a control target. The film thickness may be, for example, a value indicating the thickness of the film at the center or may be an average film thickness. The film quality may include the refractive index (RI), the film density, the amount of dopant, and the like of the film.

In the following, an outline of a configuration of the deposition apparatus 200 according to the present embodiment will be described. The deposition apparatus 200 according to the present embodiment includes an approximately cylindrical processing chamber 4 having a longitudinal direction as the vertical direction. The processing chamber 4 has a double-tube configuration including a cylindrical inner cylinder 6 and an outer cylinder 8 that has a ceiling and that is located concentrically outside of the inner cylinder 6. The inner cylinder 6 and the outer cylinder 8 are formed of a refractory material such as quartz.

The inner cylinder 6 and the outer cylinder 8 are held at lower ends of the inner cylinder 6 and the outer cylinder 8 by a manifold 10 formed of stainless steel or the like. The manifold 10 is fixed, for example, to a base plate, which is not illustrated. Here, the manifold 10 forms an internal space that is approximately cylindrical together with the inner cylinder 6 and the outer cylinder 8, and forms a part of the processing chamber 4.

That is, the processing chamber 4 includes, for example, the inner cylinder 6 and the outer cylinder 8 that are formed of a refractory material, such as quartz, and the manifold 10 formed of stainless steel or the like, and the manifold 10 is provided at a lower part of a side surface of the processing chamber 4 so as to hold the inner cylinder 6 and the outer cylinder 8 from below.

The manifold 10 includes a gas introduction section 20 that introduces, in the processing chamber 4, various gases, such as a deposition gas used in the deposition step, a process gas such as etching gas used in the etching step, a purge gas used in the purge step, and the like. Here, FIG. 1 illustrates a configuration in which one gas introduction section 20 is provided, but the configuration is not limited thereto. Multiple gas introduction sections 20 may be provided depending on the type of the used gas or the like.

The type of the deposition gas is not particularly limited, and the deposition gas is appropriately selected in accordance with the type of the film to be deposited or the like. For example, when a polysilicon film is deposited on a wafer W, for example, a gas containing a monosilane (SiH₄) may be used as the deposition gas.

The type of the etching gas is not particularly limited, and the etching gas is appropriately selected in accordance with the type of a deposition material to be etched or the like. The type of the purge gas is not particularly limited, and, for example, an inert gas such a nitrogen (N₂) gas may be used.

An introduction pipe 22 for introducing various gases into the processing chamber 4 is connected to the gas introduction section 20. Here, a flow rate adjuster 24 such as a mass flow controller that adjusts the gas flow rate and a valve (which is not illustrated) are interposed in the introduction pipe 22.

Additionally, the manifold 10 includes a gas exhaust 30 that exhausts the inside of the processing chamber 4. Exhaust piping 36 including a vacuum pump 32 configured to perform pressure reduction control on the inside of the processing chamber 4, a variable opening degree valve 34, and the like are connected to the gas exhaust 30.

At the lower end of the manifold 10, a furnace port 40 is formed, and at the furnace port 40, a lid 42 that has a disk shape and that is formed of stainless steel, for example, is provided. The lid 42 is provided, for example, such that the lid 42 can be lifted and lowered by a lifting mechanism 44 that functions as a boat elevator, and is configured to airtightly seal the furnace port 40.

A heat insulating cylinder 46 formed of quartz is mounted on the lid 42, for example. On the heat insulating cylinder 46, for example, a wafer boat 48, formed of quartz, that holds, for example, about 50 to 175 wafers (substrates) W, horizontally with predetermined intervals is placed.

The wafer boat 48 is loaded into (carried in) the processing chamber 4 by lifting the lid 42 by using the lifting mechanism 44, and various substrate processing is performed on the wafers W held in the wafer boat 48. After various substrate processing is performed, the lid 42 is lowered by using the lifting mechanism 44 to unload (carry out) the wafer boat 48 from the processing chamber 4 to a loading area below.

In the present embodiment, processing from a loading step in which the wafer boat 48 is loaded into (carried in) the processing chamber 4 to an unloading step in which the wafer boat 48 is unloaded (carried out) from the processing chamber 4 to the loading area below is referred to as a substrate processing process.

That is, the substrate processing process according to the present embodiment includes the loading step (the carrying-in step), an unloading step (the carrying-out step), and multiple steps performed between the loading step and the unloading step. The multiple steps performed between the loading process and the unloading process include a deposition step.

On the outer periphery of the processing chamber 4, for example, a cylindrical heater 60 that can control heating of the processing chamber 4 to a predetermined temperature is provided.

The heater 60 is divided into multiple zones, and heaters 60a to 60f are provided from an upper side to a lower side in the vertical direction. The heaters 60a to 60f each are configured to independently control the amount of heat generation by using power controllers 62a to 62f. Additionally, on the inner wall of the inner cylinder 6 and/or the outer wall of the outer cylinder 8, temperature sensors 65a to 65f corresponding to the heaters 60a to 60f are provided.

Multiple wafers W mounted on the wafer boat 48 form one batch, and various types of substrate processing are performed in units of batches. At least one or more wafers W mounted on the wafer boat 48 is preferably monitored wafers. Additionally, the monitored wafers are preferably disposed corresponding to the respective heaters 60a to 60f.

The deposition system 1 according to the present embodiment includes, for example, a group of monitoring sensors that monitors the environment of the deposition performed by the deposition system 1. The group of monitoring sensors includes, for example, sensors 63 and 64 illustrated in FIG. 1. In the following description, information containing the respective output values of the group of monitoring sensors may be referred to as environmental information. The values of the sensors 63 and 64 are examples of the environmental information that cannot be controlled or is not controlled by the deposition apparatus 200.

In the deposition system 1, an environment is prepared such that the respective output values of the group of monitoring sensors become predetermined values before performing the substrate processing process. Thus, the respective output values of the group of monitoring sensors are not adjusted while performing the substrate processing process. In other words, the environmental information is not adjusted while performing the substrate processing process.

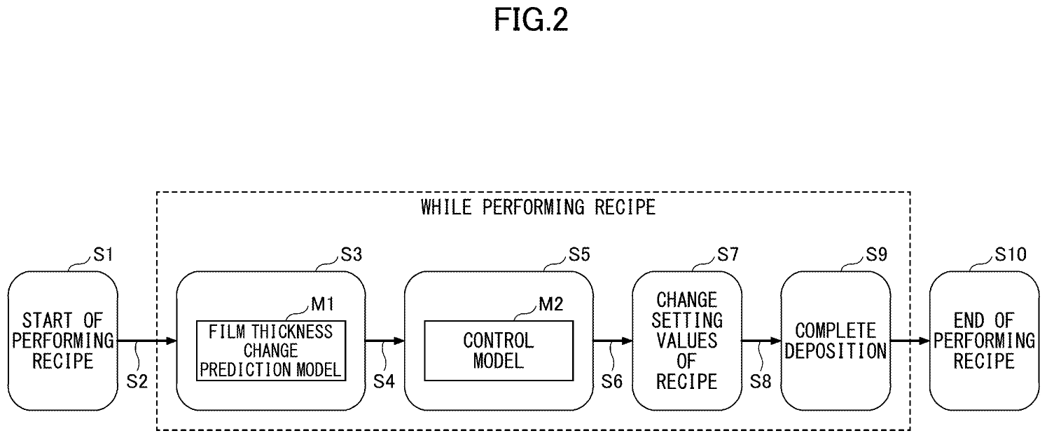

Next, an outline of an operation of the deposition system 1 according to the present embodiment will be described with reference to FIG. 2. FIG. 2 is a diagram for explaining the outline of the operation of the deposition system.

In the deposition system 1 according to the present embodiment, the control device 100 predicts a change amount from a target value of the control target based on the environmental information while performing the substrate processing process, and controls the deposition apparatus 200 so as to cause a value of the control target to approach the target value by using a predicted result.

Therefore, in the present embodiment, even when the environmental information changes while performing the substrate processing process, the influence of the change of the environmental information on the deposition result can be suppressed, and the reproducibility of the deposition result can be improved.

A case in which the environmental information changes is, for example, a case in which the processing chamber 4 is opened to perform maintenance of the deposition apparatus 200 or the like.

Specifically, the control device 100 includes a film thickness change prediction model M1 (hereinafter, the prediction model M1) and a control model M2.

The control device 100 predicts, in response to log information about the deposition apparatus 200 being input to the prediction model M1, the change amount from the target value of the control target due to the change of the environmental information included in the log information, and outputs a predicted value. That is, the prediction model M1 of the present embodiment is used to predict the change amount from the target value of the control target due to the influence of the environmental information that cannot be adjusted (controlled) or is not adjusted (controlled) while performing the substrate processing process, and used to output the predicted value. However, the prediction model M1 may be also used to predict the change amount from the target value of the control target due to the influence of the environmental information that can be adjusted while performing the substrate processing process and used to output the predicted value.

The control device 100 uses the control model M2 to derive the optimum deposition condition that causes the control target to approach the target value based on the predicted value output from the prediction model M1. The deposition condition is a condition defined in a recipe that defines a procedure of the substrate processing process, and is adjusted while performing the substrate processing process. That is, the control model M2 is used to adjust the deposition condition that can be adjusted while performing the substrate processing process.

The log information according to the present embodiment will be described.

The log information according to the present embodiment is information indicating a state of the deposition apparatus 200 that can be continuously collected as long as the deposition apparatus 200 is in operation. Specifically, the log information is obtained in various steps, such as the loading step, the deposition step, and the unloading step, and includes the output values of the group of various sensors disposed in the deposition apparatus 200, and includes the respective output values of the group of monitoring sensors. That is, the log information includes the environmental information.

In the following description, a detection item detected from the deposition apparatus 200 may be referred to as a parameter, and the output values of various sensors may be referred to as parameter values. The parameters also include an item of the environmental information that cannot be adjusted in the recipe, and the parameter values include the output values of various sensors that obtain the environmental information. Thus, the log information includes combinations of the parameters, equal in number to the number of the groups of sensors, and parameter values.

Specific examples of the combination of the parameter and the value of the parameter include, for example, “the temperature of the substrate”, “an output value of the temperature sensor”, and the like.

Additionally, specific examples of the combination of the parameter and the value of the parameter include, for example, “the pressure in the loading area” and “a pressure sensor value”, “a gas supply amount” and “a flow meter value”, and “the gas supply time” and “a timer value to time a time duration from the supply start to the stop time”. Further, specific examples of the combination of the parameter and the value of the parameter may include “the temperature of the dew point in the loading area” and “an output value of the temperature sensor for dew point detection”.

In the following, the substrate processing process in the deposition system 1 according to the present embodiment will be described.

The control device 100 starts performing the recipe defining the procedure of the substrate processing process (step S1). From the start of performing the recipe, the control device 100 collects the log information about the deposition apparatus 200 and inputs the collected log information to the prediction model M1 at the timing of performing the prediction by using the prediction model M1 (step S2). The timing of performing the prediction by using the prediction model M1 will be described in detail below. The log information collected from the start of performing the recipe is log information collected upon the start of currently performing the recipe or immediately after the start of currently performing the recipe, and does not include log information collected from the start of previously performing the recipe.

The prediction model M1 predicts the change amount from the target value of the control target by using the log information (step S3) and outputs a predicted value (step S4). In other words, the prediction model M1 predicts the change amount from the target value of the control target due to the change in the environmental information included in the log information.

When the control device 100 acquires the predicted value, the control device 100 inputs the predicted value to the control model M2, and derives the optimum deposition condition in which the value of the control target approaches the target value most (i.e., the most closely) by using the control model M2 (step S5). Next, the control device 100 acquires the optimum deposition condition derived from the control model M2 (step S6) and updates a deposition condition defined in the recipe to the deposition condition derived in step S5 (step S7).

Subsequently, the control device 100 causes the deposition apparatus 200 to perform the deposition step based on the updated recipe (step S8), completes the deposition (step S9), and ends performing the recipe (step S10).

As described above, the control device 100 according to the present embodiment predicts the change amount of the control target by using the log information collected from the start of performing the recipe every time the substrate processing process is performed, derives the optimum deposition condition based on the predicted result, and updates the recipe. The control device 100 then deposits the film according to the updated recipe.

Therefore, according to the present embodiment, when the substrate processing process is performed under the same condition, the reproducibility of the deposition result can be improved for each substrate processing process.

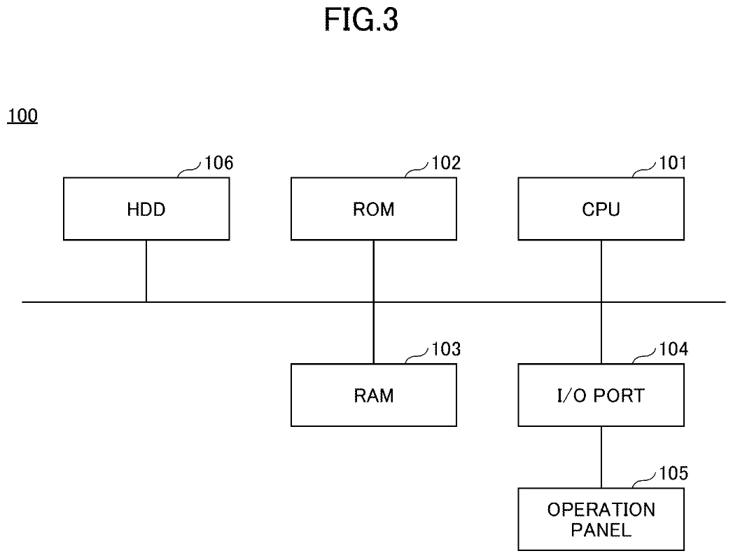

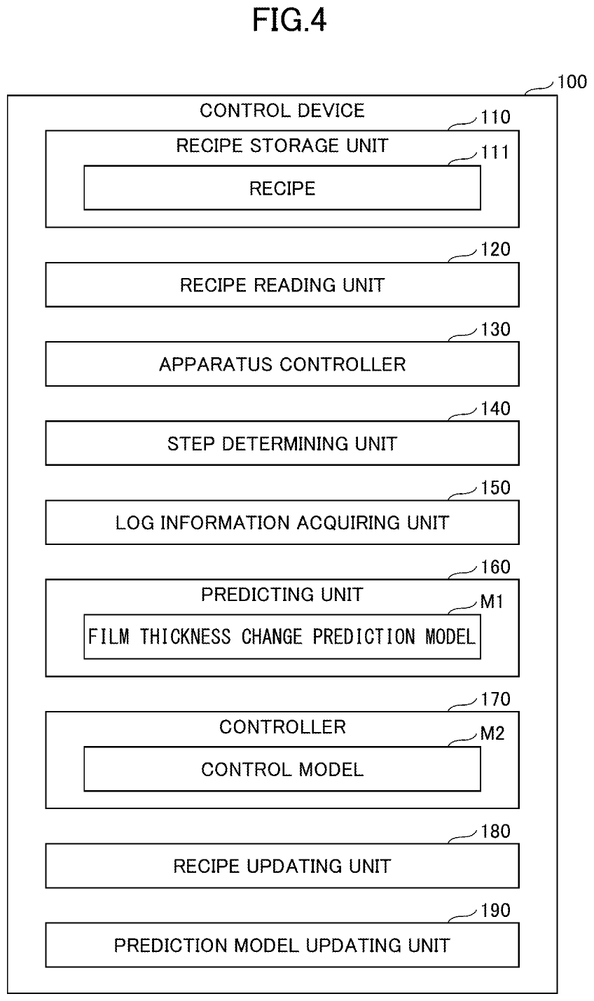

Next, the control device 100 according to the present embodiment will be described with reference to FIG. 3 and FIG. 4. FIG. 3 is a diagram illustrating an example of a hardware configuration of the control device.

The control device includes a central processing unit (CPU) 101, a read only memory (ROM) 102, a random access memory (RAM) 103, an I/O port 104, an operation panel 105, and a hard disk drive (HDD) 106, each of which is connected by a bus.

The CPU 101 controls the operation of the control device 100 based on the model, the recipe, and the like stored in a storage device such as the HDD 106.

The ROM 102 is configured by an electrically erasable programmable ROM (EEPROM), a flash memory, a hard disk, or the like, and is a storage medium that stores an operation program or the like of the CPU 101.

The RAM 103 functions as a work area of the CPU 101 or the like.

The I/O port 104 acquires output values of sensors that detect a temperature, a pressure, a gas flow rate, and the like from the deposition apparatus 200 and supplies the acquired output values to the CPU 101. Additionally, the I/O port 104 outputs a control signal output by the CPU 101 to various sections of the deposition apparatus 200 (the power controller 62, a controller (not illustrated) of the variable opening degree valve 34, the flow rate adjuster 24, and the like). Additionally, the operation panel 105 used by an operator to operate the deposition apparatus 200 is connected to the I/O port 104.

The HDD 106 is an auxiliary storage device and may store the recipe that is information defining the procedure of the substrate processing process, a program implementing the function of the control device 100 described later, various models including the above-described prediction model M1 and control model M2, and the like.

Next, the function of the control device 100 according to the present embodiment will be described with reference to FIG. 4. FIG. 4 is a diagram for explaining the function of the control device.

The control device 100 according to the present embodiment includes a recipe storage unit 110, a recipe reading unit 120, an apparatus controller 130, a step determining unit 140, a log information acquiring unit 150, a predicting unit 160, a controller 170, a recipe updating unit 180, and a prediction model updating unit 190.

A recipe 111 is stored in the recipe storage unit 110. The recipe 111 is information defining the procedure of the substrate processing process. Specifically, the recipe 111 defines the temperature change, the pressure change, the timing of starting and stopping of the supply of various gases, the supply amount of various gases, and the like from when the wafer W is transferred into the deposition apparatus 200 to when the processed wafer W is transferred from the deposition apparatus 200.

Additionally, the substrate processing process defined in the recipe 111 includes multiple steps. In the recipe 111, a procedure, and a condition of the deposition apparatus 200 when performing the procedure are defined for each of the steps included in the substrate processing process. The steps included in the substrate processing process include a gas supply step, a loading step, a deposition step, and an unloading step. The conditions of the deposition apparatus 200 include a deposition condition that is a condition of the deposition apparatus 200 in the deposition step included in the substrate processing process.

The condition of the deposition apparatus 200 included in the recipe 111 is, for example, a condition defining a combination of a target value of a parameter to be adjusted during the substrate processing process and an object and control content to be adjusted during the substrate processing process to adjust a value of the parameter. For example, a target value (a control value) is set in the recipe 111 for each item of the temperature, the pressure, the gas flow rate, the processing time, and the like in the processing chamber 4 as the condition of the deposition apparatus 200.

In the following description, the object to be adjusted during the substrate processing process may be referred to as a control knob. In the present embodiment, the value of the parameter to be adjusted during the substrate processing process is a value of a parameter having the control knob and can be adjusted by the control knob. In the present embodiment, the adjustment amount of the control knob of the parameter is calculated based on the control model M2 during the substrate processing process.

An example of the condition of the deposition apparatus 200 is a combination of, for example, a target value of the temperature of the wafer W detected by the temperature sensors 65a to 65f and an output value of the heaters 60a to 60f.

In this case, the detection items detected by the temperature sensors 65a to 65f correspond to the parameters, and the temperatures detected by the temperature sensors 65a to 65f correspond to the values of the parameters. Additionally, the heaters 60a to 60f correspond to the control knobs, and the output values of the heaters 60a to 60f correspond to the control contents of the control knobs.

Further, examples of the condition of the deposition apparatus 200 include a combination of the pressure in the processing chamber 4 detected by the pressure sensor; and the rotation speed of the vacuum pump 32 and the opening degree of the variable opening degree valve 34, and a combination of the gas flow rate detected by the flow meter and the adjustment amount of the flow rate adjuster 24, and the like.

The recipe reading unit 120 reads the recipe 111 stored in the recipe storage unit 110. The apparatus controller 130 performs the substrate processing process defined in the recipe 111 that is read. In the following description, performing the substrate processing process defined in the recipe 111 may be described as performing the recipe 111. Specifically, the apparatus controller 130 controls the deposition apparatus 200 based on the recipe 111.

The step determining unit 140 determines whether the process proceeds from the start of performing the recipe 111 to a specific step. The specific step is a step between the start of performing the recipe 111 and the start of the deposition step. The specific step will be described in detail below.

The log information acquiring unit 150 acquires output values of the group of the sensors of the deposition apparatus 200 through the I/O port 104 after the start of performing the recipe 111. In other words, the log information acquiring unit 150 collects the log information about the deposition apparatus 200 immediately after the start of performing the recipe 111 or upon the start of performing the recipe 111.

Additionally, the log information acquiring unit 150 inputs the collected log information to the predicting unit 160 if the step determining unit 140 determines that the process has proceeded to the specific step.

The predicting unit 160 stores the prediction model (the film thickness change prediction model) M1 in advance, predicts the change amount from the target value of the control target due to the change of the environmental information included in the log information, in response to the log information about the deposition apparatus 200 being input, to calculate the predicted value and output the calculated predicted value. That is, it can be said that the predicting unit 160 is a functional unit achieved by the prediction model M1.

The controller 170 stores the control model M2 in advance. When the controller 170 acquires the predicted value output from the predicting unit 160, the controller 170 inputs the predicted value into the control model M2 and acquires the optimum deposition condition output from the control model M2. That is, it can be said that the controller 170 is a functional unit achieved by the control model M2.

More specifically, the controller 170 acquires a value representing the adjustment content of the control knob output from the control model M2 as a correction amount. For example, when the control knobs are the heaters 60a to 60f, the controller 170 acquires the adjustment amount of the output values of the heaters 60a to 60f as the correction amount.

The recipe updating unit 180 updates the deposition condition included in the recipe 111 to the optimum deposition condition derived from the controller 170. Specifically, the recipe updating unit 180 updates the control contents of the control knob included in the deposition condition in accordance with the correction amount calculated based on the optimum deposition condition.

The prediction model updating unit 190 updates the prediction model M1 based on a deposition result of the deposition performed by the deposition system 1.

In the following, the generation of the prediction model M1 according to the present embodiment will be described. Here, the generation of the prediction model M1 may be performed in advance by the control device 100 or may be performed by an information processing device other than the control device 100 or the like.

In the present embodiment, the multivariate analysis is performed using process data including the log information about the deposition apparatus 200 and the film thickness of the deposited film when the deposition was performed in the past, and a parameter that greatly contributes to the change in the film thickness is identified from the log information. In other words, in the present embodiment, a parameter that is correlated with the change in the film thickness is identified from the log information.

In the present embodiment, the prediction model M1 is generated using parameter step information about the identified parameter. The parameter step information is information representing values of the parameter in all the steps included in the substrate processing process. Here, the prediction model M1 may be generated by identifying the parameter that correlates with the change in the film thickness from the log information and using the step information about the identified parameter.

In the present embodiment, with respect to each of the parameters included in the log information, a correlation between a value of the parameter for each step and the change in the film thickness is analyzed, and the parameter that correlates with the change in the film thickness is identified. In the following description, the parameter that correlates with the change in the film thickness is referred to as a change factor parameter. That is, among the parameters included in the log information, the change factor parameter is a parameter in which the contribution to the change in the film thickness is great when the film is deposited under the same condition as in the previous deposition step.

In the present embodiment, the change factor parameter may be identified from among parameters included in the environmental information in the log information. The parameter included in the environmental information is a parameter that cannot be controlled or is not controlled by the deposition apparatus 200. In other words, the parameter included in the environmental information is a parameter that does not have the control knob.

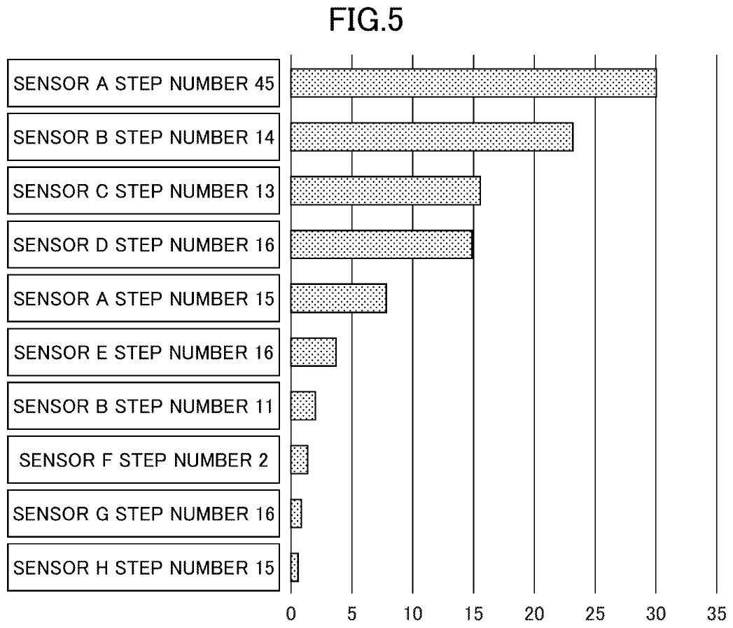

FIG. 5 is a diagram illustrating the identification of the change factor parameter. In the example of FIG. 5, the respective values of the sensors A to H are shown as the values of the parameter per step. In the example of FIG. 5, it can be seen that the value of the sensor A in step number 45 has the greatest contribution to the change in the film thickness.

Therefore, here, the detection item corresponding to the sensor A (the temperature detected by the sensor A) is identified as the change factor parameter.

In the following, a case, in which the prediction model M1 is generated by using the temperature detected by the sensor A, which is one of the group of monitoring sensors, as the change factor parameter, is described.

In the present embodiment, a parameter in which the contribution to the change in the film thickness is greater than or equal to a predetermined threshold value may be used as the change factor parameter. Thus, for example, in FIG. 5, the detecting items corresponding to the sensors B, C, and D may also be identified as the change factor parameters.

According to the present embodiment, when multiple change factor parameters are present, the prediction model M1 corresponding to the change factor parameter may be created for each of the change factor parameters.

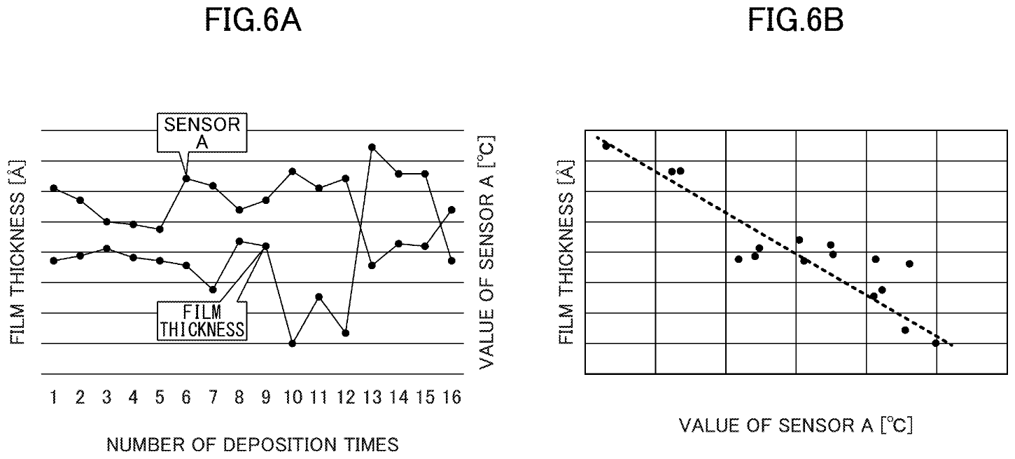

FIG. 6A and FIG. 6B are graphs each indicating a correlation between a value of the change factor parameter and the change in the film thickness. FIG. 6A is a graph illustrating a relationship between the number of substrate processing processes (the number of deposition times); and a value of the sensor A and the film thickness. FIG. 6B is a graph illustrating a relationship between a value of the sensor A and the film thickness.

In FIG. 6A, the horizontal axis indicates the number of substrate processing processes (the number of deposition times), the left vertical axis indicates the film thickness, and the right vertical axis indicates the value of the sensor A. Here, the film thickness of the present embodiment is the thickness of the center of the film (the center film thickness).

As indicated in FIG. 6A, as the value of the sensor A increases, the value of the film thickness decreases, and as the value of the sensor A decreases, the value of the film thickness increases. Therefore, as indicated in FIG. 6B, the relationship between the value of the sensor A and the film thickness is negatively correlated, that is, the value of the film thickness decreases as the value of the sensor A increases.

In the present embodiment, the change factor parameter is identified from among the parameters included in the environmental information, as described, and the prediction model M1 is generated using the correlation between the change factor parameter and the film thickness, so that the effect on the film thickness and the film quality due to the change in the parameter in which the control knob is not present can be predicted.

Thus, in the present embodiment, the control model M2 allows the recipe to be updated so as to minimize the predicted change in the film thickness and the film quality based on the environmental information while performing the substrate processing process.

In the present embodiment, the change factor parameter is identified from among the parameters included in the environmental information, but the embodiment is not limited thereto. The change factor parameter may be identified from parameters that are not included in the environmental information. That is, the change factor parameter may be a parameter for which the control knob is present.

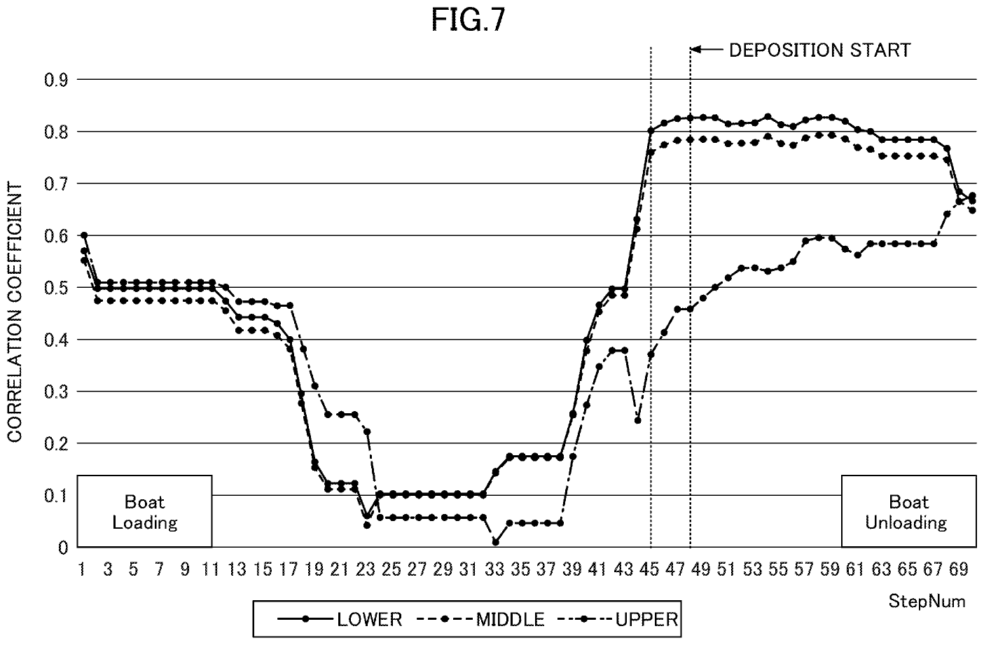

Next, a specific step of starting the prediction by using the prediction model M1 will be described with reference to FIG. 7. FIG. 7 is a graph for explaining a relationship between a step included in the substrate processing process; and a correlation between the value of the change factor parameter and the film thickness.

In FIG. 7, the vertical axis represents a correlation coefficient between the value of the change factor parameter and the film thickness, and the horizontal axis represents all the step numbers included in the substrate processing process.

Additionally, FIG. 7 indicates a relationship between the correlation coefficient with the film thickness and the step number for each of three sensors A that are provided at a lower portion, a middle portion, and an upper portion of the processing chamber 4.

The solid line in FIG. 7 indicates a relationship between a correlation coefficient between the value of the sensor A provided at the lower portion of the processing chamber 4 and the film thickness; and each of the steps included in the substrate processing process. The dashed line in FIG. 7 indicates a relationship of a correlation coefficient between the value of the sensor A at the middle portion of the processing chamber 4 and the film thickness; and each of the steps. The dash-dot-dash line in FIG. 7 indicates a relationship between a correlation coefficient between the value of the sensor A provided at the upper portion of the processing chamber 4 and the film thickness; and each of the steps.

In FIG. 7, the steps from step number 1 to step number 3 are the loading step, the steps from step number 58 to step number 69 are the unloading step, and the step of step number 48 is a first step of the deposition step.

In the example of FIG. 7, in the steps of step number 45 and later, the value of the correlation coefficient indicated by each of the solid line, the dashed line, and the dash-dot-dash line increases. That is, FIG. 7 indicates that the values of the sensor A in the steps of step number 45 and later greatly contribute to the change in the film thickness of the film deposited on the wafer W in the deposition step starting from step number 48.

Thus, in the present embodiment, the specific step of starting the prediction by using the prediction model M1 corresponding to the sensor A is set to the step of step number 45.

In this case, after the start of performing the recipe 111 and when performing the process up to step number 47, the control device 100 inputs the log information collected during the steps from step number 45 to step number 47 into the prediction model M1, and acquires a predicted value from the prediction model M1.

The control device 100 derives the optimum deposition condition by using the predicted value based on the control model M2 and updates the recipe 111 before the step of step number 48. In other words, the control device 100 derives the optimum deposition condition based on the predicted value and updates the recipe 111 based on the derived deposition condition before the step of starting the deposition step.

In the present embodiment, the step number in which the correlation coefficient between the change factor parameter and the film thickness becomes great is defined as the specific step, so that the predicted value of the change amount of the control target can be predicted based on the log information representing the state of the deposition apparatus 200 immediately before the specific step. Therefore, in the present embodiment, the accuracy of predicting the change amount of the control target due to the influence of the environmental information can be improved.

Here, in the present embodiment, a step in which the value of the correlation coefficient is greater than or equal to a predetermined threshold value may be used as the specific step. The step number indicating the specific step in the prediction model M1 may be retained by the step determining unit 140.

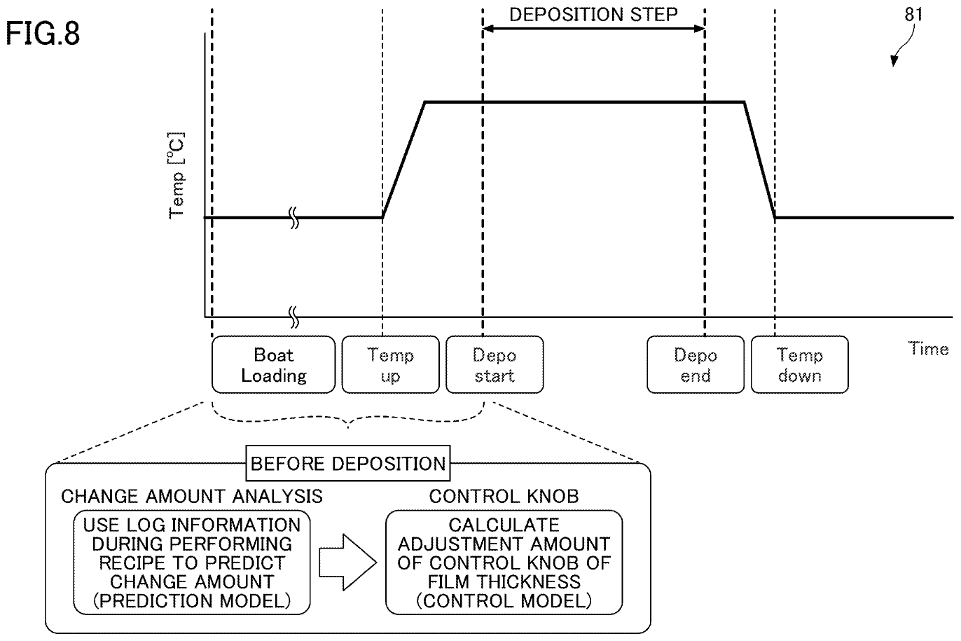

In the following, the deriving of the optimum deposition condition performed by the control model M2 according to the present embodiment will be described with reference to FIG. 8. FIG. 8 is a diagram for explaining a relationship between the prediction model and the control model.

The control model M2 of the present embodiment identifies a parameter to minimize the change amount by adjusting a value of the parameter, in response to the predicted value of the change amount being output by the prediction model M1. Then, the control model M2 calculates the adjustment amount of the control knob corresponding to the identified parameter.

FIG. 8 illustrates a case in which the temperature detected by the temperature sensor 65a is identified as the parameter, and in the graph 81 of FIG. 8, the vertical axis indicates an output value of the temperature sensor 65a and the horizontal axis indicates the time.

In the example of FIG. 8, the predicted value of the change amount of the film thickness is calculated by using the prediction model M1 before the deposition step starts and after the loading step starts, and the adjustment amount of the control knob that causes the film thickness to approach the target value is calculated by using the control model M2. Here, the prediction model M1 at this time is generated by using the detection item detected by the sensor A as the change factor parameter.

Because the control knob corresponding to the temperature sensor 65a is the heater 60a, the control model M2 calculates the adjustment amount of the output value of the heater 60a as the adjustment amount of the control knob.

Here, the sensor A is a sensor that does not have a control knob included in the group of the monitoring sensors, and the temperature sensor 65a is a sensor that has the control knob. That is, in the present embodiment, the change factor parameter that may cause the change from the target value of the control target is different from the parameter whose value is adjusted to cause the predicted change to approach the target value.

More specifically, the change factor parameter is a parameter that does not have a control knob and whose value cannot be adjusted during the substrate processing process. The parameter identified by the control model M2 is a parameter that has a control knob and whose value can be adjusted during the substrate processing process.

In the present embodiment, as described, by adjusting the parameter having the control knob, the change, predicted by using the change factor parameter that is highly correlated with the film thickness in the control target, can be reduced.

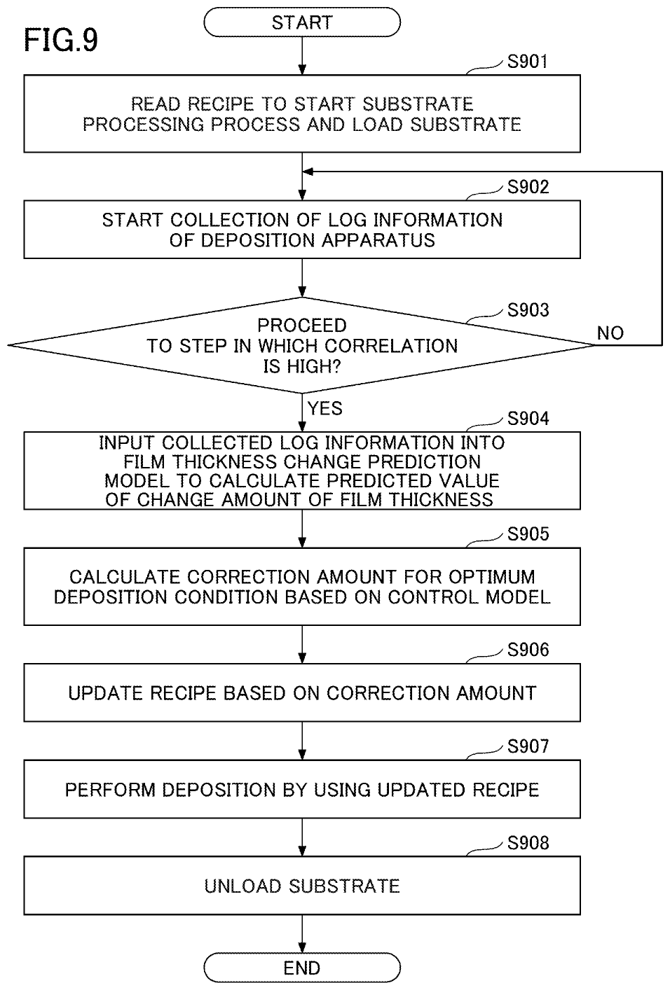

Next, an operation of the control device 100 according to the present embodiment will be described with reference to FIG. 9. FIG. 9 is a flowchart illustrating the operation of the control device.

In step S901, in the control device 100 according to the present embodiment, the recipe reading unit 120 reads the recipe 111 from the recipe storage unit 110, the apparatus controller 130 starts the substrate processing process, and the wafer W (the substrate) is loaded.

Subsequently, in step S902, the log information acquiring unit 150 in the control device 100 starts collecting the log information output from the deposition apparatus 200. The processing of step S901 and step S902 may start simultaneously, or the processing of step S902 may start immediately after the processing of step S901.

Subsequently, in step S903, the step determining unit 140 in the control device 100 determines whether the process proceeds to the specific step in the substrate processing process. In step S903, if the process does not proceed to the specific step, the control device 100 waits until the process proceeds to the specific step.

In step S903, if the process proceeds to the specific step, the control device 100 inputs the log information collected by the log information acquiring unit 150 to the predicting unit 160 and the predicting unit 160 calculates the predicted value of the change amount from the target value of the control target in step S904.

Specifically, if the log information is acquired from the log information acquiring unit 150, the predicting unit 160 inputs the acquired log information into the prediction model M1, causes the prediction model M1 to calculate the predicted value, and outputs the predicted value calculated by the prediction model M1.

Subsequently, in step S905, the control device 100 inputs the predicted value output from the predicting unit 160 to the controller 170 and acquires the correction amount of the control knob that causes the prediction value to approach zero.

Specifically, the controller 170 inputs the predicted value output from the predicting unit 160 into the control model M2, causes the control model M2 to calculate the correction amount of the control knob that causes the predicted value to approach zero, and outputs the correction amount calculated by the control model M2.

Subsequently, in step S906, the recipe updating unit 180 in the control device 100 corrects the adjustment amount of the control knob included in the recipe 111 based on the correction amount acquired in step S905.

Subsequently, in step S907, the apparatus controller 130 in the control device 100 controls the deposition apparatus 200 based on the recipe 111 updated in step S906 to perform the deposition.

Subsequently, in step S908, the apparatus controller 130 in the control device 100 unloads the wafer W and ends performing the substrate processing process.

Here, the prediction model updating unit 190 in the control device 100 according to the present embodiment may update the prediction model M1 based on the measurement result of the film thickness of the film deposited by the process illustrated in FIG. 9 and the log information.

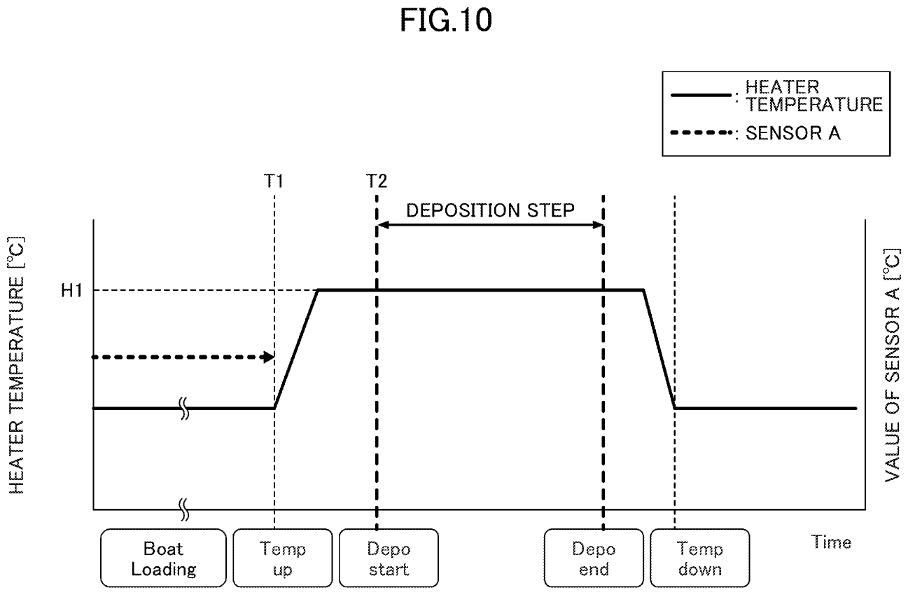

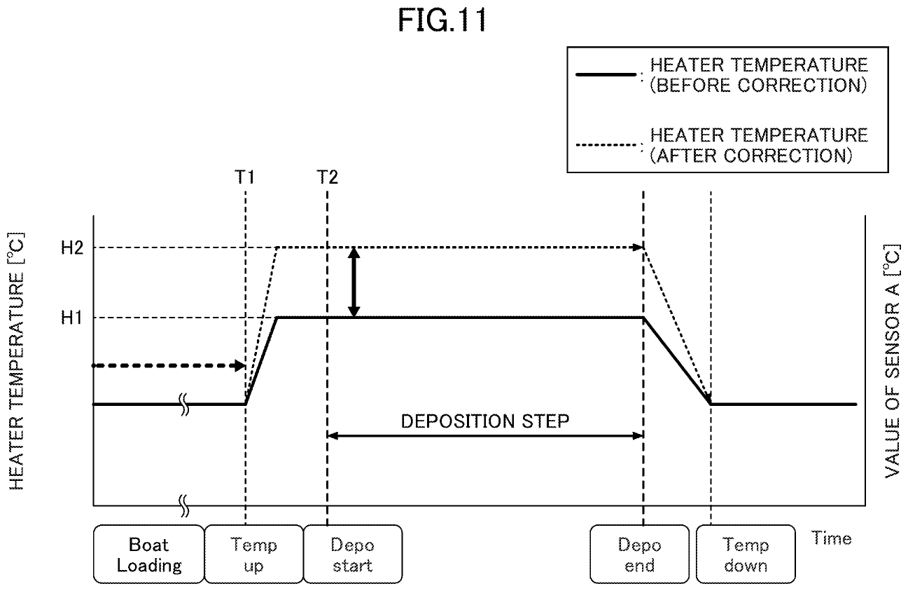

In the following, the processing of the control device 100 will be specifically described with reference to FIG. 10 and FIG. 11. FIG. 10 is a first diagram for explaining the processing of the control device, and FIG. 11 is a second diagram for explaining the processing of the control device.

The examples of FIG. 10 and FIG. 11 indicate a case in which the prediction model M1 is defined to use the detection item detected by the sensor A as the change factor parameter, and the parameter whose value is adjusted by the control model M2 is the heater temperature.

In the graphs illustrated in FIG. 10 and FIG. 11, the left vertical axis indicates the temperature of the heater, the right vertical axis indicates the temperature of the sensor A, and the horizontal axis indicates the time.

Additionally, in FIG. 10 and FIG. 11, the timing T1 indicates a timing when the specific step starts, and the timing T2 indicates a timing when the deposition step starts.

The control device 100 of the present embodiment starts collecting the log information including the output value of the sensor A when the substrate processing process is started and the wafer W is loaded. At this time, the value of the heater temperature is set to H1 [° C.] according to the deposition condition of the recipe 111.

When the substrate processing process proceeds and the timing T1 is reached, the control device 100 inputs the log information collected until then into the prediction model M1 and updates the deposition condition based on the predicted value output from the prediction model M1 by using the control model M2. Here, a case, in which the value of the temperature of the heater included in the optimum deposition condition derived by the control model M2 is H2, is indicated.

In this case, the control device 100 updates the value of the temperature of the heater included in the deposition condition of the recipe 111 from H1 to H2.

As illustrated in FIG. 11, by this update, the temperature of the heater is set to H2 [° C.] by the timing T2 at which the deposition step starts, and the deposition step is performed in a state in which the value of the temperature of the heater is updated to H2 [° C.].

In the present embodiment, the case in which, in the recipe 111, the value to be updated by the recipe updating unit 180 is the value of the heater temperature is described, but the value to be updated is not limited thereto. The value to be updated by the recipe updating unit 180 changes depending on the optimum deposition condition derived by the controller 170, and any value defined in the recipe 111 may be updated. Thus, in the present embodiment, for example, the gas flow rate, the gas supply time, the pressure in the processing chamber 4, and the like may be updated.

As described above, in the present embodiment, based on the log information collected from the start of performing the substrate processing process to the specific step, the deposition condition defined in the recipe 111 is updated. In the present embodiment, because this process is performed every time the substrate processing process is performed, the deposition can be performed under the optimum deposition condition that does not depend on the environment of the deposition system 1 before the deposition step is started. Therefore, according to the present embodiment, the reproducibility of the deposition result can be improved.

In the above-described embodiment, the log information input into the prediction model M1 is the log information collected during the period from the start of performing the substrate processing process (from the start of performing the recipe) to the specific step, but is not limited thereto. The log information input into the prediction model M1 may be, for example, the output values of the group of respective sensors that are acquired in a step immediately before the specific step.

Additionally, in the above-described embodiment, the condition derived by the control model M2 is the optimum deposition condition, but is not limited thereto. The condition derived by the control model M2 may be a condition other than the deposition condition. In other words, the control model M2 may derive the optimum condition in a step other than the deposition step.

Additionally, the control model M2 is a model that outputs the correction amount of the control knob to cause the predicted value to approach zero, but is not limited thereto. The control model M2 may output the optimum value of the adjustment amount of the control knob. In this case, the control device 100 may update the adjustment amount of the control knob defined in the current recipe 111 to the adjustment amount output from the control model M2.

Additionally, in the present embodiment, the log information from when the substrate processing process starts to the time immediately before the start of the deposition step is collected and is input into the prediction model M1, but the log information is not limited thereto.

In the present embodiment, the log information that is input to the prediction model M1 may include log information collected while performing the deposition step. In the present embodiment, by including the log information acquired while performing the deposition step in the input of the prediction model M1, the influence of the change in the environment while performing the deposition step on the control target can be reduced.

Additionally, in the above-described embodiment, the control device 100 is a single information processing device, but is not limited thereto. The control device 100 may be implemented by multiple information processing devices. Additionally, the control device 100 may be included in the deposition apparatus 200.

Additionally, in the present embodiment, a batch-type device in which multiple wafers W mounted on the wafer boat 48 form a batch and the deposition step is performed on a batch-by-batch basis is described as an example, but the device is not limited thereto. For example, a semi-batch type device in which the deposition step is performed on multiple wafers W mounted on a holder as a whole or a single-sheet type device in which the deposition step is performed one by one may be used.

According to the present disclosure, the reproducibility of the deposition result can be improved.

The deposition system and method according to the embodiments disclosed herein should be considered to be exemplary in all respects and not restrictive. The embodiments can be modified and improved in various forms without departing from the appended claims and spirit thereof. The matters described in the above embodiments may employ other configurations to the extent not inconsistent, and may be combined to the extent not inconsistent.

What is claimed is:

1. A deposition system comprising:
a deposition apparatus configured to deposit a film on a substrate; and
a control device;
wherein the control device includes
a recipe storage unit configured to store a recipe that defines a procedure of a substrate processing process performed by the deposition apparatus; and
a processor configured to calculate a predicted value of a change amount from a target value of a control target indicating a film thickness or a film quality of a film deposited in a deposition step included in the substrate processing process, by using log information about the deposition apparatus, the log information being collected from when the substrate processing process based on the recipe starts, and
update the recipe based on the predicted value so as to cause a value of the control target to approach the target value before the deposition step.

2. The deposition system as claimed in claim 1, wherein the log information is collected from when the substrate processing process based on the recipe starts to before start of the deposition step.

3. The deposition system as claimed in claim 1, wherein the log information is collected from when the substrate processing process based on the recipe starts to before completion of the deposition step.

4. The deposition system as claimed in claim 1,
wherein the log information includes a change factor parameter that correlates with the film thickness or the film quality, and
wherein the processor calculates the predicted value of the change amount of the control target, the change amount being caused by the change factor parameter.

5. The deposition system as claimed in claim 4, wherein the processor derives a condition based on the predicted value, the condition being a condition in which the value of the control target approaches the target value most, and updates a condition defined in the recipe to the derived condition.

6. The deposition system as claimed in claim 5, wherein the change factor parameter includes a value of a sensor that cannot be controlled or is not controlled by the deposition apparatus.

7. The deposition system as claimed in claim 6, wherein the processor calculates the predicted value when the deposition apparatus proceeds to a step in which a correlation with the control target is greater than a predetermined threshold in the substrate processing process, by using the log information collected from when the substrate processing process based on the recipe starts to when the deposition apparatus proceeds to the step in which the correlation is greater than the predetermined threshold.

8. The deposition system as claimed in claim 1, wherein the processor updates the recipe every time the substrate processing process is performed.

9. A deposition method performed by a deposition system including a deposition apparatus configured to deposit a film on a substrate and a control device, the deposition method comprising:
calculating, by the control device, a predicted value of a change amount from a target value of a control target indicating a film thickness or a film quality of a film deposited in a deposition step included in the substrate processing process, by using log information about the deposition apparatus, the log information being collected from when a procedure of the substrate processing process starts, and the procedure of the substrate processing process being defined in a recipe stored in a recipe storage unit, and
updating, by the control device, the recipe based on the predicted value so as to cause a value of the control target to approach the target value before the deposition step.
